(19) United States
(12) Patent Application Publication
(10) Pub. No.: US 2012/0122282 A1
(43) Pub. Date: May 17, 2012

(54) METHOD OF MANUFACTURING SEMICONDUCTOR DEVICES

(75) Inventor: Hyun Yul KWON, Icheon-si (KR)

(73) Assignee: HYNIX SEMICONDUCTOR INC., Icheon-si (KR)

(21) Appl. No.: 13/297,647

(22) Filed: Nov. 16, 2011

(30) Foreign Application Priority Data
Nov. 17, 2010 (KR) 10-2010-0114395

(51) Int. Cl. H01L 21/336; H01L 21/266

(52) U.S. Cl. 438/264; 438/533; 257/E21.422; 257/E21.346

(57) ABSTRACT

A method of manufacturing semiconductor devices includes forming a plurality of lines arranged in a direction over a semiconductor substrate, forming mask patterns over the semiconductor substrate wherein the mask patterns intersect the lines, and forming junctions in the semiconductor substrate between the lines by performing an ion implantation process.

### CROSS-REFERENCE TO RELATED APPLICATION

Priority is claimed to Korean patent application number 10-2010-0114395 filed on Nov. 17, 2010, the entire disclosure of which is incorporated by reference herein.

### BACKGROUND

Exemplary embodiments relate generally to a method of manufacturing semiconductor devices and, more particularly, to a method of manufacturing semiconductor devices which can reduce/minimize the occurrence of a gate line bending phenomenon.

A semiconductor device includes a cell region and a peripheral region. The cell region includes a plurality of memory cells for storing data, and the peripheral region includes various functional blocks for programming, reading, and otherwise controlling the memory cells. Here, the peripheral region may include not only low voltage transistors but also high voltage transistors for supplying high voltages. In the case of known nonvolatile memory devices, the cell region includes memory cell transistors and select transistors. The gate terminals of the memory cell transistors are interconnected to form word lines, and the gate terminals of the select transistors are interconnected to form select lines. Also, the gate terminals of the high voltage and low voltage transistors are interconnected respectively to form high voltage and low voltage lines.

The word lines, the select lines, and the high voltage and low voltage lines are called gate lines. According to a known nonvolatile memory device, the density of the gate lines in the cell region is higher than the density of the gate lines in the peripheral region. In other words, an interval between each gate line in the cell region is narrower than that in the peripheral region.

With continuing efforts to highly integrate the semiconductor devices, the line width of the gate line is gradually narrowed, and a ratio of the height and the line width of the gate line is also increased. However, increasing the ratio of the height and the line width could lead to a gate line bending phenomenon which will be described in detail with reference to the drawings.

FIG. 1 is a three dimensional (3-D) view and FIG. 2 is a photograph illustrating above mentioned phenomenon.

Referring to FIG. 1, after gate lines 12 (GL) are formed on a semiconductor substrate 10, an ion implantation process for forming junctions in the semiconductor substrate 10 is performed. Here, the semiconductor substrate 10 has active regions and isolation regions. The ion implantation process for forming the junction is performed for each of a cell region (not shown) and a peripheral region (not shown). For example, in order to form the junction in the cell region, the ion implantation process is performed using mask patterns having an open window corresponding to a region in which the junction is to be formed. A process of forming the mask patterns is described in detail below.

In order to form the mask patterns, a photoresist layer for the mask patterns is formed, and exposure and development processes are performed to form the mask patterns. The development process is performed to remove the exposed photoresist layer using a developer 14. In this case, the gate lines 12 may be bent because tension F due to the developer 14 and the photoresist layer is generated between the gate lines 12. The tension F is determined according to an interval S between the gate lines 12, the height H of the gate line 12, and the length L of the gate line 12. The tension F is described in more detail with reference to Equation1 below.

$$F = \frac{cos Θ}{S} \times HL \qquad [ Equation 1 ]$$

Referring to Equation1, the tension F between the gate lines 12 is in inverse proportion to the interval S between the gate lines 12 and is proportional to cosine θ (θ is the angle formed by the gate lines 12 and the semiconductor substrate 10), the height H and the length L of the gate lines 12. Here, the length L of the gate lines refers to the length of the gate lines 12 exposed between the mask patterns. In other words, as the length of the gate lines 12 exposed between the mask patterns increases, the tension F between the gate lines 12 increases. When the tension F between the gate lines 12 increases, the gate lines 12 may be bent by the tension F.

Referring to FIG. 2, a gate line bending phenomenon could lead to a defect 40. For example, if a gate line is leaning against an adjacent but separate gate line, a power supplied to the gate line may also be supplied to the adjacent gate line, and thus reliability of the semiconductor device may be deteriorated.

### BRIEF SUMMARY

Exemplary embodiments relate to a method of manufacturing semiconductor devices, which can reduce/minimize the occurrence of a gate line bending phenomenon.

A method of manufacturing semiconductor devices according to an embodiment of the present invention includes forming a plurality of lines arranged in one direction on a semiconductor substrate, forming mask patterns on the semiconductor substrate in a direction orthogonal to the lines, forming junctions in the mask patterns and part of the semiconductor substrate, exposed between the lines, by performing an ion implantation process.

Before forming the plurality of lines, active regions and isolation regions are formed in the semiconductor substrate in the direction orthogonal to the lines.

The mask patterns are formed of photoresist patterns.

Forming the mask patterns includes forming a photoresist layer for the mask patterns over the semiconductor substrate so that the lines are covered and forming photoresist patterns in the direction orthogonal to the lines by performing exposure and development processes.

The lines include gate lines which are formed by sequentially stacking a tunnel dielectric layer, a floating gate, a dielectric layer, and a control gate over the semiconductor substrate and patterning the tunnel dielectric layer, the floating gate, the dielectric layer, and the control gate.

After forming the junctions, the mask patterns are removed and an insulating layer is formed over the semiconductor substrate from which the mask patterns have been removed so that the lines are covered.

The insulating layer is formed of an oxide layer for an interlayer dielectric layer.

The mask patterns are formed on regions where well pick-up units will be formed, from the semiconductor substrate.

The method further includes etching part of the insulating layer so that regions where well pick-up units will be formed, from the semiconductor substrate, are exposed and forming the well pick-up units in the exposed semiconductor substrate by performing an ion implantation process, after forming the insulating layer.

A method of manufacturing semiconductor devices according to an embodiment of the present invention includes defining a plurality of memory cell block regions on a semiconductor substrate in a matrix form, forming a plurality of gate lines arranged in one direction on the semiconductor substrate, forming a plurality of mask patterns on a dummy region between the memory cell block regions in a direction orthogonal to the direction where the gate lines are arranged, forming a junction in the semiconductor substrate exposed between the mask patterns, removing the mask patterns, forming an insulating layer over the semiconductor substrate from which the mask patterns have been removed so that the gate lines are covered, etching part of the insulating layer so that regions where well pick-up units will be formed, from the dummy region, are exposed, and forming well pick-up units in the exposed dummy regions.

The mask patterns are formed of a plurality of photoresist patterns orthogonal to the gate lines.

Forming the mask patterns includes forming a photoresist layer for the mask patterns over the semiconductor substrate so that the gate lines are covered and forming photoresist patterns orthogonal to the gate lines by performing exposure and development processes.

The gate lines are formed by sequentially stacking a tunnel dielectric layer, a floating gate, a dielectric layer, and a control gate over the semiconductor substrate and patterning the tunnel dielectric layer, the conductive layer for the floating gate, the dielectric layer, and the conductive layer for the control gate.

Forming the well pick-up units includes forming mask patterns for the well pick-up units, having opening portions formed in regions where the well pick-up units will be formed, over the insulating layer, etching part of the insulating layer to expose part of the semiconductor substrate by performing an etch process using the mask patterns for the well pick-up units as an etch mask, and forming the well pick-up units in the exposed semiconductor substrate by performing an ion implantation process.

A method of manufacturing semiconductor devices according to an embodiment of the present invention includes forming a plurality of lines arranged in one direction on a semiconductor substrate in which a cell region and a peripheral region are defined, forming a photoresist layer over the semiconductor substrate so that the lines are covered, forming photoresist patterns orthogonal to the lines, formed in the cell region, by performing exposure and development processes for the photoresist layer, forming junctions in part of the semiconductor substrate exposed between the photoresist patterns and the lines, removing the photoresist patterns, forming an insulating layer over the semiconductor substrate from which the photoresist patterns have been removed so that the lines are covered, exposing part of the semiconductor substrate by performing an etch process for removing part of the insulating layer, and forming well pick-up units in the exposed semiconductor substrate.

Lines formed on the cell region, from among the lines, comprise a plurality of drain select lines, word lines, and source select lines, and lines formed on the peripheral region, from among the lines, comprise a plurality of high voltage and low voltage lines.

Forming the well pick-up units is performed by an ion implantation process for implanting impurities into the exposed semiconductor substrate.

### BRIEF DESCRIPTION OF THE DRAWINGS

FIG. 1 is a 3-D view illustrating a gate line bending phenomenon;

FIG. 2 is a photograph illustrating the gate line bending phenomenon;

FIGS. 3A to 3F are plan views illustrating a method of manufacturing semiconductor memory devices according to an embodiment of the present invention;

FIG. 4 is a 3-D view illustrating an embodiment of the present invention; and

FIG. 5 is a detailed cross-sectional view of gate lines according to an embodiment of the present invention.

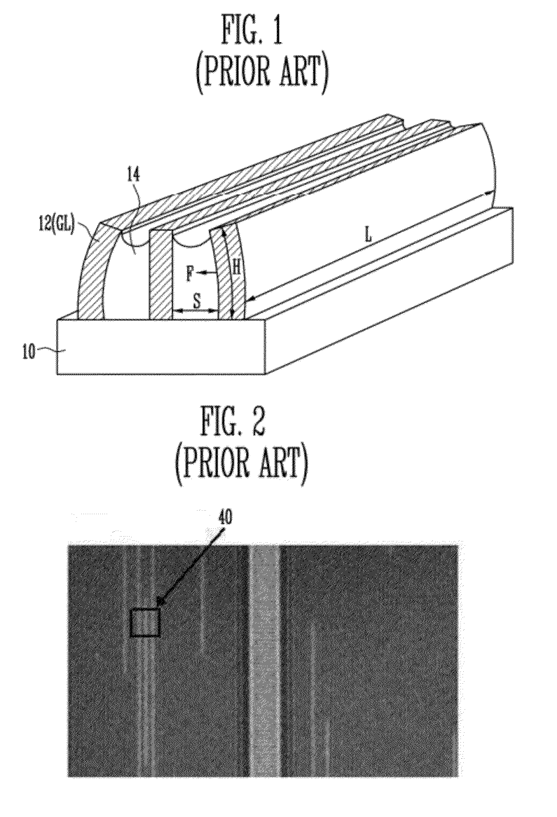

### DESCRIPTION OF EMBODIMENTS

Hereinafter, embodiments of the present invention will be described in detail with reference to the accompanying drawings. The figures are provided to allow those having ordinary skill in the art to understand the scope of the embodiments of the disclosure.

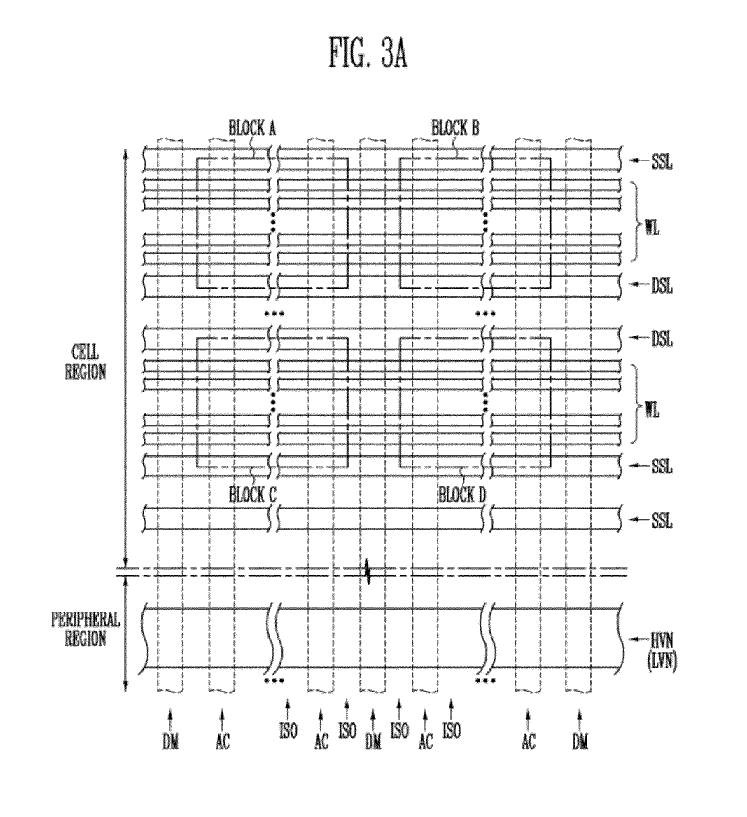

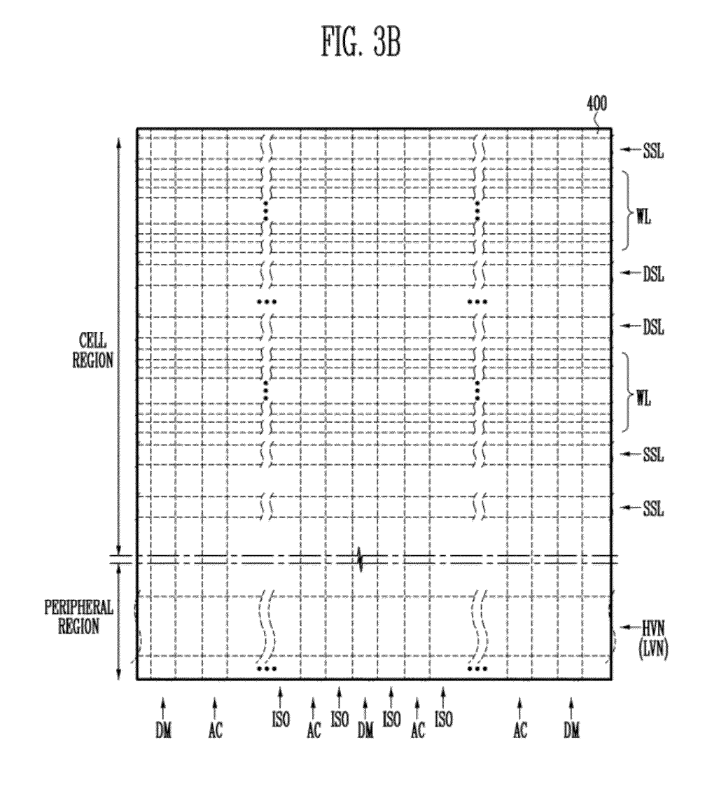

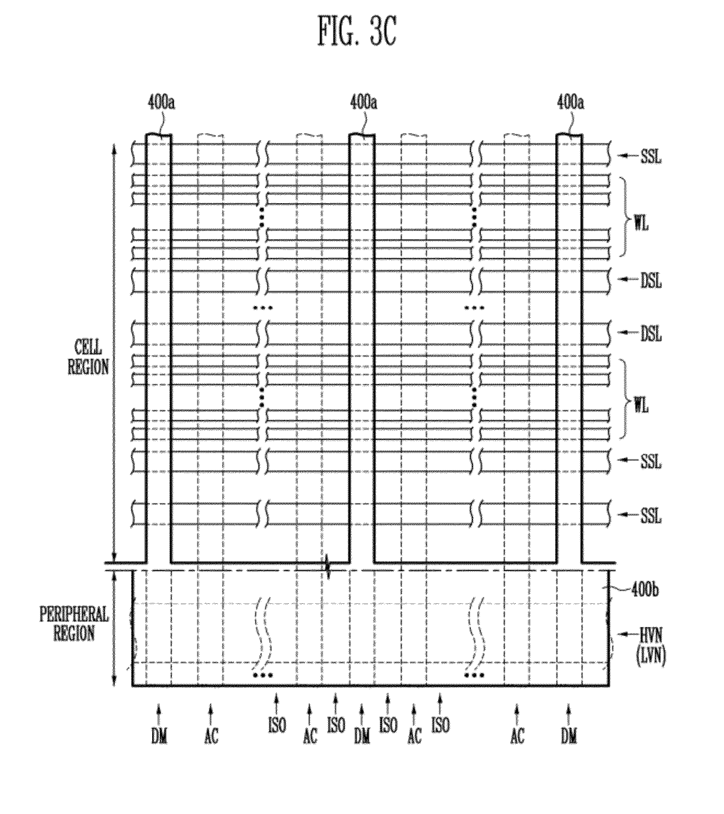

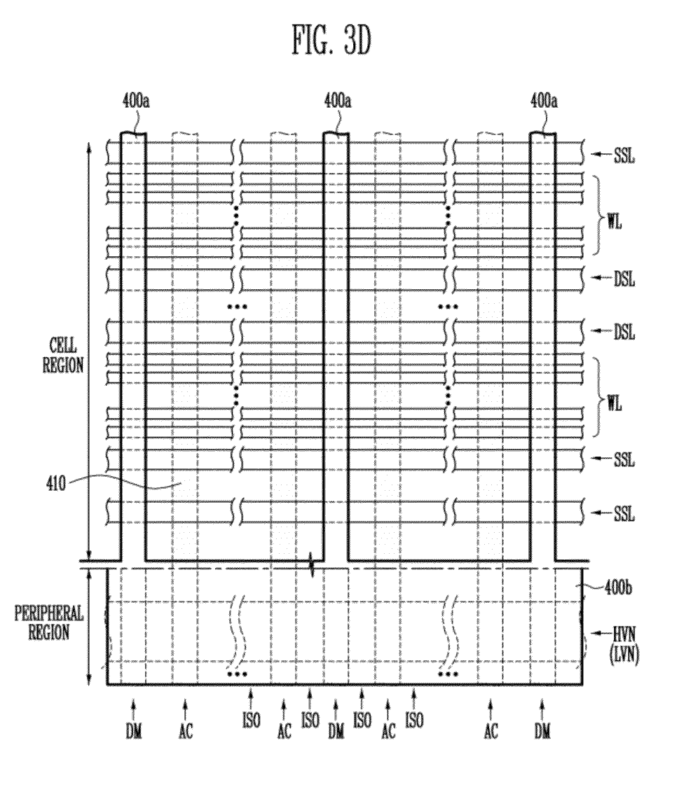

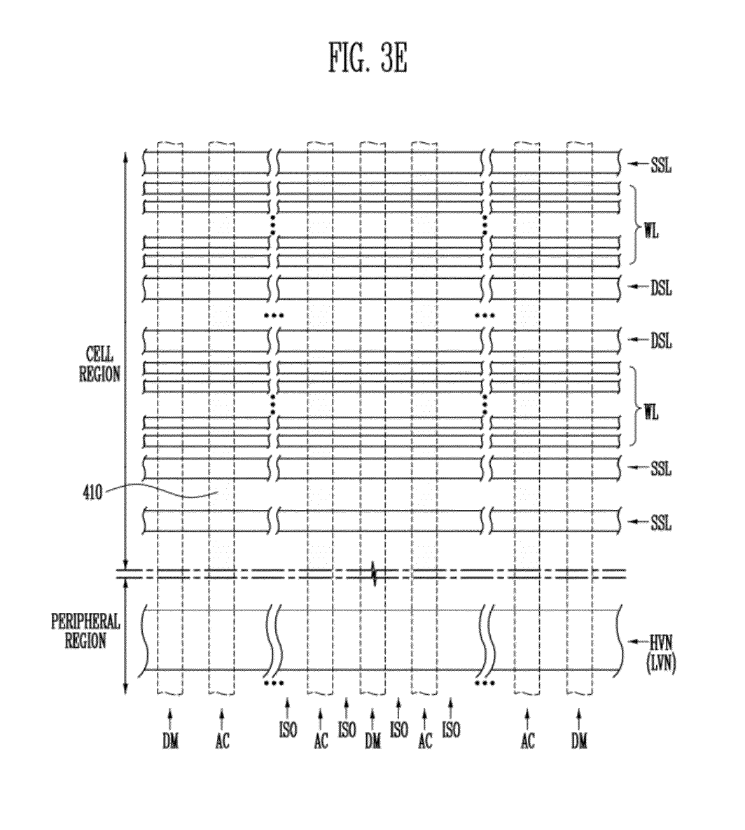

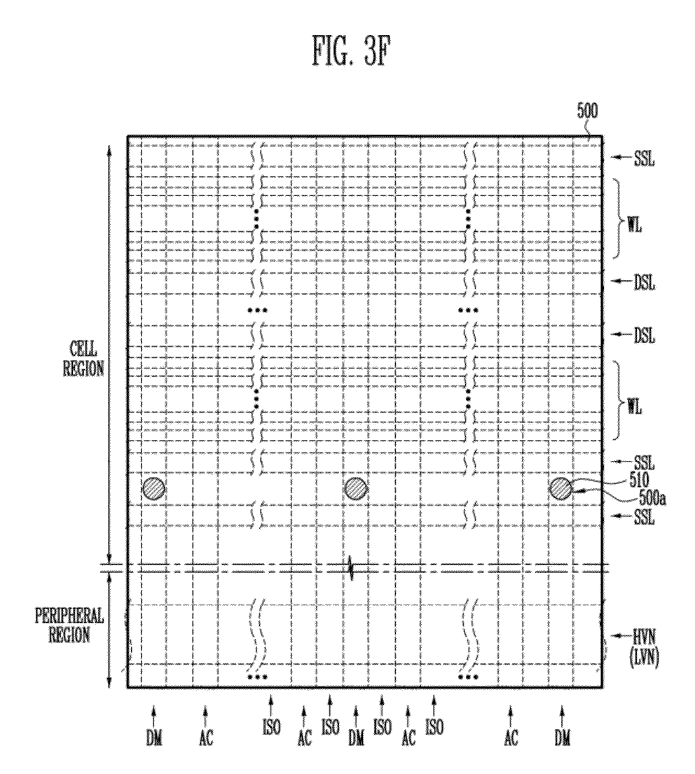

FIGS. 3A to 3F are plan views illustrating a method of manufacturing semiconductor memory devices according to an embodiment of the present invention.

Referring to FIG. 3A, a cell region and a peripheral region are formed on a semiconductor substrate in which a well is formed. Here, the cell region includes a plurality of memory cell block regions where data is stored, and the peripheral region is a region for programming, reading, and otherwise controlling the memory cells. In addition, active regions AC and isolation regions ISO are defined in the cell region and the peripheral region, and an isolation layer is formed in the isolation region.

Also, gate lines are formed in the cell region and the peripheral region, and the gate lines are arranged in a direction on a semiconductor substrate.

FIG. 5 is a detailed cross-sectional view of gate lines according to an embodiment of the present invention.

Referring to FIG. 5, each of the gate lines is formed by stacking a tunnel dielectric layer 502, a floating gate 504, a dielectric layer 506, and a control gate 508 over a semiconductor substrate 500 and then patterning them. The patterns become drain select transistors, memory cells, and source select transistors. According to an example, the drain select transistors and the source select transistors may be formed so that the floating gate 504 and the control gate 508 come into contact with each other by forming a hole of the dielectric layer 506. In addition, the plurality of memory cells between the drain select transistor and the source select transistor forms a string and the memory cell block includes a plurality of the strings. The gate terminals of the drain select transistor are interconnected to form a drain select line DSL, and the gate terminals of the memory cells interconnected to form word lines. Also, the gate terminals of the source select transistors are interconnected to form a source select line SSL.

Referring back to FIG. 3A, the gate lines include the drain select lines DSL, the word lines WL, the source select lines SSL, and high voltage and low voltage lines HVN and LVN. Here, the drain select lines DSL, the word lines WL, and the source select lines SSL are formed on the cell region, and the high voltage and low voltage lines HVN and LVN are formed on the peripheral region.

According to an example, the cell region includes a plurality of memory cell blocks Block A to Block D, and each of the memory cell blocks Block A to Block D includes a source select line SSL, a drain select line DSL, and a plurality of word lines WL formed between the source select line SSL and the drain select line DSL.

An active region AC between the memory cell block A and the memory cell block B is called a dummy region DM, and a well pick-up unit (not shown) is formed on the dummy region DM in a subsequent process.

The peripheral region includes the high voltage and low voltage lines HVN and LVN formed on the semiconductor substrate in which the active regions AC and isolation regions ISO are formed.

The gate lines of the high voltage and low voltage lines HVN and LVN are formed in the peripheral region. The high voltage and low voltage lines HVN and LVN may have a larger line width and larger intervals between the gate lines because they use voltage higher than the gate lines DSL, WL and SSL formed in the cell region. Accordingly, the density of the gate lines may be lower in the peripheral region than in the cell region.

Referring to FIG. 3B, after the gate lines WL, SSL, DSL, HVN, and LVN are formed, a photoresist layer 400 for the mask patterns is formed on the cell region and the peripheral region. The photoresist layer may be formed using a spin-coating method.

Referring to FIG. 3C, an exposure region is formed by performing an exposure process for the semiconductor substrate, on which the photoresist layer 400 is formed, using a reticle, and then the exposure region is removed by performing a development process. Accordingly, the first mask pattern 400b covering the peripheral region is formed and the second mask patterns 400a for preventing the gate lines WL, SSL, and DSL, formed in the cell region, from being bent are formed, according to an example, at the same time.

Referring to FIG. 3D, a process for forming junctions 410 is performed.

The second mask patterns 400a play the role of preventing a phenomenon in which the gate lines WL, SSL, and DSL formed in the cell region are bent by a developer and the photoresist layer (refer to 400 of FIG. 3B) in a process of developing the photoresist layer.

Each of the second mask patterns 400a is formed on the dummy region DM between the memory cell blocks. For example, the second mask pattern 400a may be formed in the dummy region DM between memory cell block regions arranged in the same direction as the gate lines, from among the plurality of memory cell block regions arranged in a matrix form. Also, the second mask pattern 400a may be formed in the dummy region DM between every two or more of the memory cell blocks.

The reason why the second mask patterns 400a play the role of preventing the gate lines WL, SSL, and DSL from being bent is described in detail below.

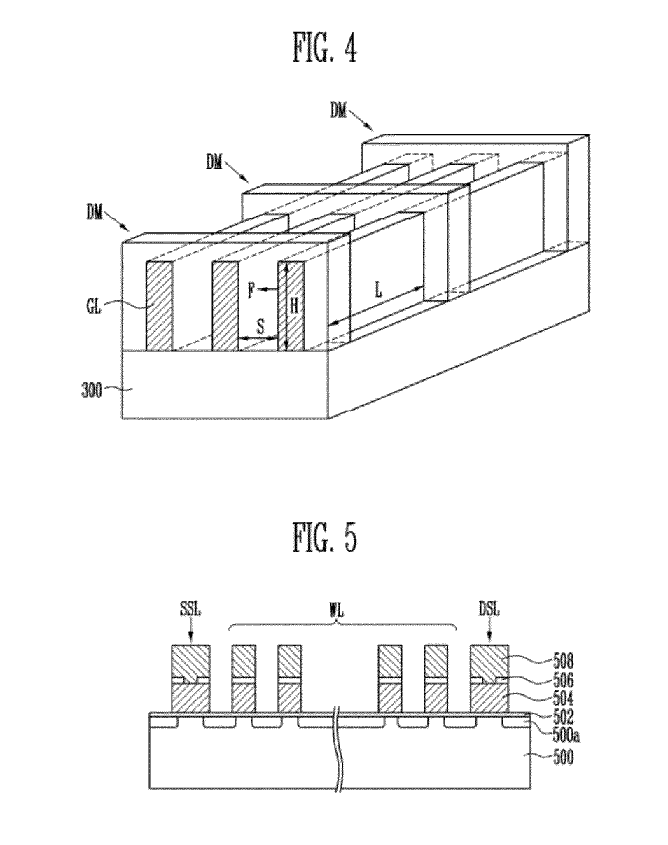

FIG. 4 is a 3-D view illustrating an embodiment of the present invention.

Referring to FIG. 4, the second mask patterns 400a functioning to support the gate lines GL are formed over semiconductor substrate 300 on which gate lines GL are formed in a direction. Here, the direction where the gate lines GL are formed intersect the direction where the second mask patterns 400a are formed. For example, the second mask patterns 400a functioning to support the gate lines GL are formed in a direction orthogonal to a direction where the gate lines GL are formed.

$$F = \frac{cos Θ}{S} \times HL \qquad [ Equation 2 ]$$

Tension F, applied to bend the gate lines GL, is shown in Equation2.

Referring to Equation2, the tension F is inversely proportional to an interval S between the gate lines GL and is proportional to cosine θ (θ is the angle formed by the gate lines GL and the semiconductor substrate 300), the height H and the length L of the gate lines GL. Accordingly, if the second mask patterns 400a are formed, the length L of exposed gate lines GL can be reduced due to the second mask patterns 400a. Accordingly, the tension F of the gate lines GL may decrease.

Referring back to FIG. 3D, the ion implantation process for forming the junctions 410 in the active regions AC, exposed between the gate lines WL, SSL, and DSL of the cell region, is performed. The ion implantation process is performed in the state in which the second mask patterns 400a are formed in the cell region and the first mask pattern 400b is formed in the peripheral region. Although the ion implantation process is performed in the state in which the second mask pattern 400a is formed in the cell region, the ion implantation process for forming the junctions 410 in the cell regions is not influenced by the second mask pattern 400a because the second mask pattern 400a is formed on the dummy region DM between the memory cell blocks (e.g., between the memory cell block A and the memory cell block B). Here, the dummy region DM is an area on which a well pick-up unit is to be formed.

Referring to FIG. 3E, both the first and the second mask patterns (refer to 400a and 400b of FIG. 3D) are removed.

Referring to FIG. 3F, according to an example, mask patterns (not shown) having openings are formed in the peripheral region. Next, junctions (not shown) are formed in the peripheral region by performing an ion implantation process, and then the mask patterns (not shown) are removed. Next, an insulating layer 500 is formed over the semiconductor substrate 100 so that the insulating layer 500 covers all the gate lines WL, SSL, DSL, and HVN. The insulating layer 500 may be formed of an oxide and used for an interlayer dielectric layer.

Next, a mask pattern as an etch mask (not shown) for forming the well pick-up units is formed over the insulating layer 500. An etch process is performed to form holes 500a in the insulating layer 500 so that a certain area of the semiconductor substrate 100 is exposed. The hole 500a is formed on the dummy region DM between the source select lines SSL. Next, an ion implantation process for implanting impurities into the exposed semiconductor substrate is performed to form the well pick-up units 510 in the dummy regions DM exposed through the respective holes 500a. Next, the mask patterns (not shown) for forming the well pick-up unit are removed.

As described above, according to the present invention, before the development process of patterning the photoresist layer, the second mask patterns 400a functioning to support the gate lines are formed. Accordingly, the occurrence of a gate line bending phenomenon can be reduced/minimized.

Furthermore, according to an example, the turn-around time is not increased because the process of forming the second mask patterns 400a is performed in the same manner as the process of forming and removing the first mask pattern 400b.

As described above, according to the present invention, a phenomenon in which the gate lines come into contact with each other can be prevented, and the yield of semiconductor devices and operational reliability of the semiconductor devices can be improved.

What is claimed is:

1. A method of manufacturing semiconductor devices, comprising:
forming a plurality of lines arranged in a direction over a semiconductor substrate;
forming mask patterns over the semiconductor substrate, wherein the mask patterns intersect the lines; and
forming junctions in the semiconductor substrate between the lines by performing an ion implantation process.

2. The method of claim 1, further comprising forming active regions and isolation regions in the semiconductor substrate in the direction orthogonal to the lines, before forming the lines.

3. The method of claim 1, wherein the mask patterns are formed of a photoresist.

4. The method of claim 1, wherein forming the mask patterns comprises:
forming a photoresist layer for the mask patterns over the semiconductor substrate so that the lines are covered; and
forming photoresist patterns in the direction orthogonal to the lines by performing exposure and development processes.

5. The method of claim 1, wherein the lines comprise gate lines which are formed by sequentially stacking a tunnel dielectric layer, a floating gate, a dielectric layer, and a control gate over the semiconductor substrate and patterning the tunnel dielectric layer, the floating gate, the dielectric layer, and the control gate.

6. The method of claim 1, further comprising:
removing the mask patterns; and
forming an insulating layer over the semiconductor substrate from which the mask patterns have been removed so that the lines are covered, after forming the junctions.

7. The method of claim 6, wherein the insulating layer is formed of an oxide.

8. The method of claim 1, wherein the mask patterns are formed on regions where well pick-up units are to be formed.

9. The method of claim 6, further comprising:
etching a portion of the insulating layer so that regions where well pick-up units are to be formed are exposed; and
forming the well pick-up units in the exposed semiconductor substrate by performing an ion implantation process.

10. A method of manufacturing semiconductor devices, comprising:
defining a plurality of memory cell block regions on a semiconductor substrate in a matrix form;
forming a plurality of gate lines arranged in a direction on the semiconductor substrate;
forming a plurality of mask patterns on a dummy region between the memory cell block regions, wherein the mask patterns intersect the gate lines;
forming a junction in the semiconductor substrate exposed between the mask patterns;
removing the mask patterns;
forming an insulating layer over the semiconductor substrate from which the mask patterns have been removed so that the gate lines are covered;
etching a portion of the insulating layer so that regions where well pick-up units are to be formed in the dummy region are exposed; and
forming well pick-up units in the exposed dummy regions.

11. The method of claim 10, wherein the mask patterns comprises a plurality of photoresist patterns orthogonal to the gate lines.

12. The method of claim 10, wherein forming the mask patterns comprises:
forming a photoresist layer for the mask patterns over the semiconductor substrate so that the gate lines are covered; and
forming photoresist patterns orthogonal to the gate lines by performing exposure and development processes.

13. The method of claim 10, wherein the gate lines are formed by sequentially stacking a tunnel dielectric layer, a floating gate, a dielectric layer, and a control gate over the semiconductor substrate and patterning the tunnel dielectric layer, the conductive layer for the floating gate, the dielectric layer, and the conductive layer for the control gate.

14. The method of claim 10, wherein forming the well pick-up units comprises:
forming mask patterns for the well pick-up units, having opening portions formed in regions where the well pick-up units are to be formed, over the insulating layer;
etching a portion of the insulating layer to expose a portion of the semiconductor substrate where the well pick-up units are to be formed using the mask patterns for the well pick-up units as an etch mask; and
forming the well pick-up units in the exposed semiconductor substrate by performing an ion implantation process.

15. A method of manufacturing semiconductor devices, comprising:
forming a plurality of lines arranged in one direction on a semiconductor substrate in which a cell region and a peripheral region are defined;
forming a photoresist layer over the semiconductor substrate so that the lines are covered;
forming photoresist patterns orthogonal to the lines, formed in the cell region, by performing exposure and development processes for the photoresist layer;
forming junctions in a portion of the semiconductor substrate exposed between the photoresist patterns and the lines;
removing the photoresist patterns;
forming an insulating layer over the semiconductor substrate from which the photoresist patterns have been removed so that the lines are covered;
performing an etch process for removing a portion of the insulating layer and exposing a portion of the semiconductor substrate; and
forming well pick-up units in the exposed semiconductor substrate.

16. The method of claim 15, wherein:
lines formed on the cell region, from among the lines, comprise a plurality of drain select lines, word lines, and source select lines, and
lines formed on the peripheral region, from among the lines, comprise a plurality of high voltage and low voltage lines.

17. The method of claim 15, wherein forming the well pick-up units is performed by an ion implantation process for implanting impurities into the exposed semiconductor substrate.
